(19) United States
(12) Patent Application Publication
(10) Pub. No.: US 2025/0202187 A1
(43) Pub. Date: Jun. 19, 2025

(54) LIGHT-EMITTING DEVICE, METHOD FOR MANUFACTURING LIGHT-EMITTING DEVICE, AND RANGING DEVICE

(71) Applicant: SONY SEMICONDUCTOR SOLUTIONS CORPORATION, KANAGAWA (JP)

(72) Inventor: SHUNSUKE FURUSE, KANAGAWA (JP)

(21) Appl. No.: 18/849,750

(22) PCT Filed: Feb. 6, 2023
(86) PCT No.: PCT/JP2023/003779

§ 371 Date: Sep. 23, 2024

(30) Foreign Application Priority Data
Mar. 31, 2022 (JP) 2022-060396

(51) Int. Cl. H01S 5/02; H01S 5/183; H01S 5/42

(52) U.S. Cl. CPC H01S 5/0206; H01S 5/18305; H01S 5/423

(57) ABSTRACT

[Problem] To provide a light-emitting device with high reliability.

[Solution] A light-emitting device 10 includes a first board 20, the first board 20 including a first substrate 21, light-emitting elements 22, each being disposed on a first side S1 of the first substrate 21 and having a multilayer film 22L, and a structure 23 disposed in an interelement region between the light-emitting elements 22 on the first side S1, the structure 23 having the same multilayer film 22L as the light-emitting element 22 or being composed of the same material as the first substrate 21.

### TECHNICAL FIELD

The present disclosure relates to a light-emitting device, a method for manufacturing the light-emitting device, and a ranging device.

### BACKGROUND ART

As a kind of semiconductor laser, surface emitting lasers such as a VCSEL (Vertical Cavity Surface Emitting Laser) have received attention in recent years (see PTL 1). A VCSEL has excellent characteristics such as low power consumption, mass-producibility at low cost, and ease of formation of a two-dimensional array. In particular, a back-side illuminated VCSEL does not require wire bonding and can be directly connected to an LDD (Laser Diode Driver) board, which facilitates downsizing and multifunctionality.

### CITATION LIST

### Patent Literature

[PTL 1]
Japanese Translation of PCT Application No. 2021-509956

### SUMMARY

### Technical Problem

An object of the present disclosure is to provide a light-emitting device and a ranging device with high reliability.

### Solution to Problem

A light-emitting device according to an aspect of the present disclosure includes a first board, the first board including: a first substrate, a light-emitting elements, each being disposed on a first side of the first substrate and having a multilayer film; and a structure that is disposed in an interelement region between the light-emitting elements on the first side, wherein the structure has the same multilayer film as the light-emitting element or is composed of the same material as the first substrate.

The first board may further include an insulator film stacked on the first side to fill a gap portion between the light-emitting element and the structure. The insulator film may be composed of an inorganic material. The first board may include a first electrode pad disposed at the top of the light-emitting element, and the top of the structure may have a height lower than the height of the top of the first electrode pad.

In the light-emitting device, the first board may further include a common electrode extended to the first side of the first substrate, the first side serving as the bottom of the gap portion between the light-emitting element and the structure.

In the light-emitting device, the first board may further include a first electrode pad disposed at the top of the light-emitting element, and a dummy electrode pad disposed at the top of the structure.

In the light-emitting device, the first board may further include a lens portion that is provided on a second side opposite to the first side of the first substrate and condenses light emitted from the light-emitting element.

The light-emitting device may further include a second board bonded to the first board, wherein the second board may include a second substrate and a second electrode pad disposed on the second substrate, and the first electrode pad of the first board and the second electrode of the second board may be bonded to each other. The first electrode pad and the second electrode pad may be bonded by direct bonding.

A method for manufacturing a light-emitting device according to an aspect of the present disclosure, the method including: a first step of producing a first board including a first substrate, light-emitting elements, each being disposed on a first side of the first substrate and having a multilayer film, a structure that is disposed in an interelement region between the light-emitting elements on the first side, and a first electrode pad disposed at the top of the light-emitting element, the structure having the same multilayer film as the light-emitting element or being composed of the same material as the first substrate; a second step of bonding the first electrode pad of the first board to a second electrode pad of a second board, the second board including a second substrate and the second electrode pad disposed on the second substrate; and a third step of reducing the thickness of the first substrate from a second side opposite to the first side.

The method for manufacturing the light-emitting device may further include a fourth step of forming a lens portion that condenses light emitted from the light-emitting element on the second side of the first substrate.

A ranging device according to an aspect of the present disclosure includes a light-emitting device, a light-receiving unit, and a distance measuring unit that measures a distance to an object on the basis of the light-emitting signal of the light-emitting device and the light-receiving signal of the light-receiving unit when the light-emitting signal of the light-emitting device is reflected by the object and is received by the light-receiving unit, the light-emitting device including: a first substrate; light-emitting elements, each being disposed on a first side of the first substrate and having a multilayer film; and a structure that is disposed in an interelement region between the light-emitting elements on the first side, wherein the structure has the same multilayer film as the light-emitting element or is composed of the same material as the first substrate.

### BRIEF DESCRIPTION OF DRAWINGS

FIG. 1 is a longitudinal section illustrating the configuration of a light-emitting device according to a first embodiment.

FIG. 2 is a cross section illustrating the configuration of the light-emitting device according to the first embodiment, the cross section being taken along line A-A of FIG. 1.

FIG. 3 is an enlarged longitudinal section illustrating a configuration around a light-emitting element of the light-emitting device according to the first embodiment, the longitudinal section indicating a B region of FIG. 1.

FIG. 4 is a front view illustrating the configuration of an LD chip in the light-emitting device of the first embodiment.

FIG. 5 is a longitudinal section illustrating the configuration of the LD chip in the light-emitting device of the first embodiment, the longitudinal section being taken along line C-C of FIG. 4.

FIG. 6A is a longitudinal section schematically illustrating a method for manufacturing the light-emitting device of the first embodiment.

FIG. 6B is a longitudinal section continued from FIG. 6A.

FIG. 6C is a longitudinal section continued from FIG. 6B.

FIG. 7 is a longitudinal section illustrating the configuration of an LD chip in a light-emitting device according to a comparative example.

FIG. 8A is a longitudinal section schematically illustrating a method for manufacturing the light-emitting device of the comparative example.

FIG. 8B is a longitudinal section continued from FIG. 8A.

FIG. 9A is a longitudinal section illustrating an example of a method for manufacturing the light-emitting device of the first embodiment.

FIG. 9B is a longitudinal section continued from FIG. 9A.

FIG. 9C is a longitudinal section continued from FIG. 9B.

FIG. 9D is a longitudinal section continued from FIG. 9C.

FIG. 9E is a longitudinal section continued from FIG. 9D.

FIG. 9F is a longitudinal section continued from FIG. 9E.

FIG. 9G is a longitudinal section continued from FIG. 9F.

FIG. 9H is a longitudinal section continued from FIG. 9G.

FIG. 9I is a longitudinal section continued from FIG. 9H.

FIG. 9J is a longitudinal section continued from FIG. 9I.

FIG. 9K is a longitudinal section continued from FIG. 9J.

FIG. 9L is a longitudinal section continued from FIG. 9K.

FIG. 10 is a longitudinal section illustrating the configuration of an LD chip in a light-emitting device according to a second embodiment.

FIG. 11 is a cross section illustrating the configuration of the LD chip in the light-emitting device of the second embodiment, the cross section being taken along line D-D of FIG. 10.

FIG. 12A is a longitudinal section illustrating an example of a method for manufacturing the light-emitting device of the second embodiment.

FIG. 12B is a longitudinal section continued from FIG. 12A.

FIG. 12C is a longitudinal section continued from FIG. 12B.

FIG. 12D is a longitudinal section continued from FIG. 12C.

FIG. 12E is a longitudinal section continued from FIG. 12D.

FIG. 13 is a longitudinal section illustrating the configuration of an LD chip in a light-emitting device according to a third embodiment.

FIG. 14 is a cross section illustrating the configuration of the LD chip in the light-emitting device of the third embodiment, the cross section being taken along line E-E of FIG. 13.

FIG. 15 is a longitudinal section illustrating the configuration of an LD chip in a light-emitting device according to a fourth embodiment.

FIG. 16 is a cross section illustrating the configuration of the LD chip in the light-emitting device of the fourth embodiment, the cross section being taken along line F-F of FIG. 15.

FIG. 17 is a front view illustrating the configuration of an LD chip in a light-emitting device according to a fifth embodiment.

FIG. 18 is a longitudinal section illustrating the configuration of the LD chip in the light-emitting device of the fifth embodiment, the longitudinal section being taken along line G-G of FIG. 17.

FIG. 19 is a cross section illustrating the configuration of the LD chip in the light-emitting device of the fifth embodiment, the cross section being taken along line H-H of FIG. 18.

FIG. 20 is a longitudinal section illustrating the configuration of an LD chip in a light-emitting device according to a sixth embodiment.

FIG. 21 is a cross section illustrating the configuration of the LD chip in the light-emitting device of the sixth embodiment, the cross section being taken along line I-I of FIG. 20.

FIG. 22 is a longitudinal section illustrating the configuration of an LD chip in a light-emitting device according to a seventh embodiment.

FIG. 23A is a longitudinal section illustrating an example of a method for manufacturing the light-emitting device of the seventh embodiment.

FIG. 23B is a longitudinal section continued from FIG. 23A.

FIG. 23C is a longitudinal section continued from FIG. 23B.

FIG. 23D is a longitudinal section continued from FIG. 23C.

FIG. 23E is a longitudinal section continued from FIG. 23D.

FIG. 23F is a longitudinal section continued from FIG. 23E.

FIG. 23G is a longitudinal section continued from FIG. 23F.

FIG. 24 is a block diagram illustrating a configuration example of a ranging device as an implementation example of the light-emitting device according to the embodiment of the present disclosure.

FIG. 25A is an explanatory drawing of an STL method.

FIG. 25B is an explanatory drawing of the ranging principle of the STL method.

FIG. 26 is a block diagram illustrating a schematic configuration example of a vehicle control system that is an example of a mobile object control system.

FIG. 27 illustrates an example of the installation positions of imaging units.

### DESCRIPTION OF EMBODIMENTS

An exemplary embodiment of the present disclosure will be described below with reference to the drawings.

### First Embodiment

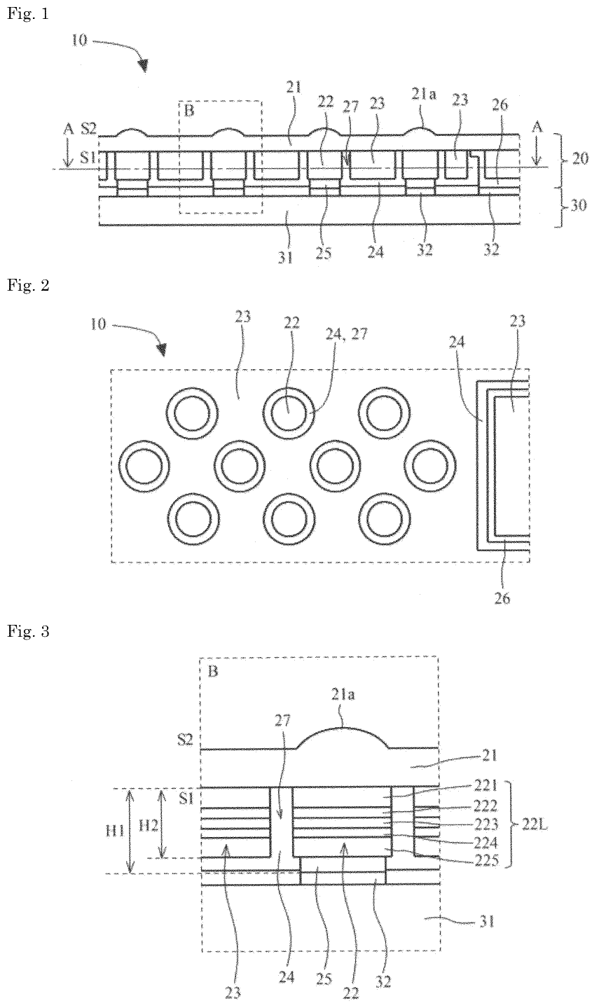

FIG. 1 is a longitudinal section illustrating the configuration of a light-emitting device 10 according to a first embodiment. FIG. 2 is a cross section illustrating the configuration of the light-emitting device 10 according to the first embodiment. The cross section is taken along line A-A of FIG. 1. FIG. 3 is an enlarged longitudinal section illustrating a configuration around a light-emitting element 22 of the light-emitting device 10 according to the first embodiment. The longitudinal section indicates a B region of FIG. 1.

The light-emitting device 10 of the first embodiment includes an LD (Laser Diode) chip 20 and an LDD board 30 joined to the LD chip 20. In the present specification, the LD chip 20 may be referred to as “first board” while the LDD board 30 may be referred to as “second board.”

The LD chip 20 includes a substrate 21, the plurality of light-emitting elements 22, a structure 23, an insulator film 24, individual electrodes 25, and a common electrode 26. Furthermore, the substrate 21 includes a plurality of lens portions 21a. The LD chip 20 also has a gap portion 27, which is filled with the insulator film 24, between the light-emitting element 22 and the structure 23.

The substrate 21 is a substrate made of a compound semiconductor such as GaAs. The substrate 21 has a front side S1 facing the LDD board 30 of the substrate 21 and a back side S2 opposite to the front side S1. In the present specification, the front side S1 of the substrate 21 will be referred to as “first side” while the back side S2 will be referred to as “second side.” Moreover, the substrate 21 of the LD chip 20 may be referred to as “first substrate.”

The light-emitting elements 22 is a back-side illuminated VCSEL having a mesa structure. The plurality of light-emitting elements 22 are dispersedly located on the first side S1 of the substrate 21. As illustrated in FIG. 3, the light-emitting element 22 is configured with a multilayer film 22L. In other words, the light-emitting element 22 includes the multilayer film 22L.

The multilayer film 22L has a structure in which a first mirror layer 221, a first spacer layer 222, an active layer 223, a second spacer layer 224, and a second mirror layer 225 are sequentially stacked from the substrate 21. The first mirror layer 221 and the second mirror layer 225 are configured with, for example, multilayer film reflectors. The light-emitting element 22 resonates laser light, which is generated in the active layer 223, between the first mirror layer 221 and the second mirror layer 225 to increase light intensity and then emits the light from the second side S2 of the substrate 21.

Although the LD chip 20 of the first embodiment includes the plurality of light-emitting elements 22, the LD chip 20 according to the technique of the present disclosure may be provided with a single light-emitting element 22. However, the technique of the present disclosure is properly applied to the LD chip 20 including the plurality of light-emitting elements 22. Thus, the LD chip 20 preferably includes the plurality of light-emitting elements 22 dispersedly located on the substrate 21.

The structure 23 is disposed in an interelement region between the dispersedly located light-emitting elements 22 on the first side S1 of the substrate 21. The interelement region refers to a region between the plurality of light-emitting elements 22. If the LD chip 20 includes the single light-emitting element 22 alone, the interelement region refers to a region other than a region where the light-emitting element 22 is located.

The structure 23 is configured with the multilayer film 22L like the light-emitting elements 22. The structure 23 reinforces the strength of the LD chip 20. In other words, the structure 23 includes the same multilayer film 22L as the light-emitting element 22. Moreover, the structure 23 reduces the volume of the insulator film 24 as compared with the case where the structure 23 is absent.

As illustrated in FIG. 3, the top of the structure 23 has a height H2 lower than a height H1 of the top of the individual electrode 25. This is because the LD chip 20 has the structure 23 covered with the insulator film 24.

As illustrated in FIG. 2, the gap portions 27 are disposed around the outer peripheries of the light-emitting elements 22 when being observed in the direction of the normal to the substrate 21. In short, the gap portions 27 are ring-shaped when being observed in the direction of the normal to the substrate 21. Moreover, the bottom of the gap portion 27 is the first side S1 of the substrate 21.

The insulator film 24 is stacked on the first side S1 of the substrate 21 so as to fill the gap portions 27 between the light-emitting elements 22 and the structure 23. Moreover, the insulator film 24 is stacked such that only the individual electrodes 25 and the common electrode 26 are exposed to the outside from among the light-emitting elements 22, the structure 23, the individual electrodes 25, and the common electrode 26. The presence of the structure 23 reduces the volume of the insulator film 24. The insulator film 24 suppresses the occurrence of noise in the light-emitting elements 22, thereby improving the reliability of the light-emitting device 10.

If the insulator film 24 fills the gap portions 27 between the light-emitting elements 22 and the structure 23, the light-emitting elements 22 and the structure 23 may be partially exposed to the outside from the insulator film 24. However, only the individual electrodes 25 and the common electrode 26 are preferably exposed to the outside from the insulator film 24 in view of, for example, suppression of the occurrence of noise in the light-emitting elements 22.

The insulator film 24 is composed of a material that has insulating properties and can be polished by CMP (Chemical Mechanical Polishing). The insulator film 24 is composed of an inorganic material, thereby further reinforcing the strength of the LD chip 20. Moreover, the insulator film 24 composed of an inorganic material can suppress the occurrence of warpage on the LD chip 20 in a high-temperature environment. Hence, the insulator film 24 is preferably composed of an inorganic material and is more preferably composed of SiO₂ or SiN.

The individual electrodes 25 are respectively disposed on the tops of the light-emitting elements 22. The individual electrode 25 is configured as an electrode pad. The individual electrode 25 is bonded to an electrode pad 32 of the LDD board 30 by direct bonding, e.g., thermocompression bonding. The individual electrode 25 is composed of a material suitable for direct bonding, e.g., thermocompression bonding. The individual electrode 25 is preferably composed of a metallic material and is more preferably composed of Cu or Au. In the present specification, the individual electrode 25 may be referred to as “first electrode pad.”

The common electrode 26 is disposed from the top of the structure 23, which is disposed near the end of the LD chip 20, to the first side S1 of the substrate 21 and is electrically connected to the substrate 21. The common electrode 26 has a portion configured as an electrode pad on the structure 23. The electrode pad of the common electrode 26 is bonded to the electrode pad 32 of the LDD board 30 by direct bonding, e.g., thermocompression bonding. The common electrode 26 is composed of a material suitable for direct bonding, e.g., thermocompression bonding. The common electrode 26 is preferably composed of a metallic material and is more preferably composed of Cu or Au.

The lens portions 21a are provided in regions overlaid on the light-emitting elements 22 on the second side S2 of the substrate 21. The lens portions 21a condense laser light emitted from the light-emitting elements 22.

The LDD board 30 includes a substrate 31 and the plurality of electrode pads 32 dispersedly located on the substrate 31. The electrode pads 32 supply driving signals to the light-emitting elements 22 of the LD chip 20. The electrode pads 32 of the LDD board 30 are bonded to the individual electrodes 25 and the common electrode 26 of the LD chip 20 by direct bonding, e.g., thermocompression bonding. The electrode pad 32 is composed of a material suitable for direct bonding, e.g., thermocompression bonding. The electrode pad 32 is preferably composed of a metallic material and is more preferably composed of Cu or Au. In the present specification, the LDD board 30 may be referred to as “second board,” the substrate 31 may be referred to as “second substrate,” and the electrode pad 32 may be referred to as “second electrode pad.”

The LD chip 20 and the LDD board 30 may be bonded via a solder joint or the like instead of using direct bonding. However, the light-emitting device 10 has a higher flatness when the LD chip 20 and the LDD board 30 are bonded by direct bonding. Thus, the LD chip 20 and the LDD board 30 are preferably bonded by direct bonding.

The LDD board 30 may include a drive circuit that generates a driving signal. In this case, the LDD board 30 performs active driving. Alternatively, the LDD board 30 may supply a voltage to the electrode pads 32 in response to a driving signal generated by an external drive circuit. In this case, the LDD board 30 performs passive driving.

A space between the LD chip 20 and the LDD board 30 may be filled with underfill. Specifically, the light-emitting device 10 may include an underfill layer between the LD chip 20 and the LDD board 30.

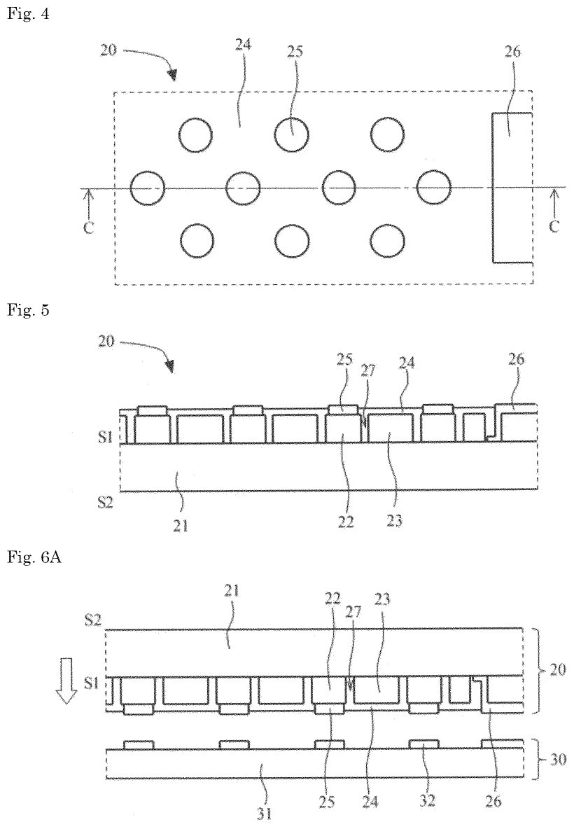

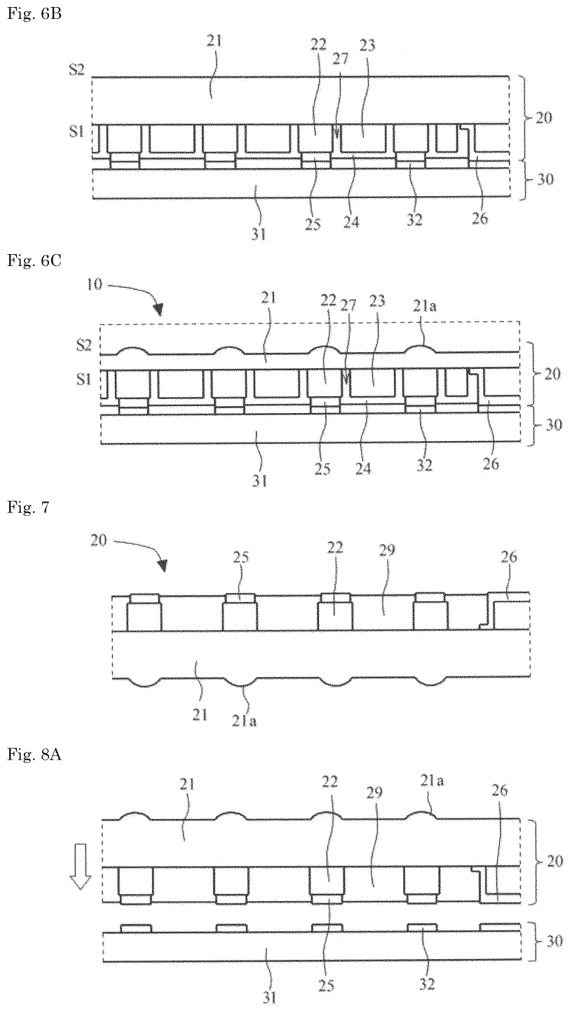

FIG. 4 is a front view illustrating the configuration of the LD chip 20 in the light-emitting device 10 of the first embodiment. FIG. 5 is a longitudinal section illustrating the configuration of the LD chip 20 in the light-emitting device 10 of the first embodiment. The longitudinal section is taken along line C-C of FIG. 4. FIGS. 6A to 6C are longitudinal sections schematically illustrating a method for manufacturing the light-emitting device 10 of the first embodiment.

FIGS. 4 and 5 illustrate the LD chip 20 to be bonded to the LDD board 30. As illustrated in FIGS. 4 and 5, the first side S1 of the LD chip 20 is covered with the insulator film 24, and only the individual electrodes 25 and the common electrode 26 are exposed to the outside from among the light-emitting elements 22, the structure 23, the individual electrodes 25, and the common electrode 26. With this configuration, the occurrence of noise in the light-emitting elements 22 can be further suppressed, thereby improving the reliability of the light-emitting device 10.

The method for manufacturing the light-emitting device 10 using the LD chip 20 configured thus will be schematically described below.

First, as illustrated in FIGS. 6A and 6B, the individual electrodes 25 and the common electrode 26 of the LD chip 20 and the electrode pads 32 of the LDD board 30 are bonded by direct bonding, e.g., thermocompression bonding. Thereafter, as illustrated in FIG. 6C, the thickness of the substrate 21 of the LD chip 20 is reduced and the lens portions 21a are formed, so that the light-emitting device is manufactured.

The presence of the structure 23 and the insulator film 24 reinforces the strength of the LD chip 20. Moreover, in the LD chip 20, the presence of the structure 23 reduces the volume of the insulator film 24. Thus, in the LD chip 20, the occurrence of warpage is suppressed even in a high-temperature environment, thereby keeping a flat bonded surface.

As described above, the LD chip 20 can keep a flat bonded surface, so that the individual electrodes 25 and the common electrode 26 of the LD chip 20 and the electrode pads 32 of the LDD board 30 can be bonded by direct bonding, e.g., thermocompression bonding. Furthermore, the strength of the LD chip 20 is reinforced and the LD chip 20 can keep a flat bonded surface, so that after the LD chip 20 is bonded to the LDD board 30, the thickness of the substrate 21 of the LD chip 20 can be reduced by polishing using CMP and the lens portions 21a can be formed on the second side S2 of the substrate 21. Hence, a higher flatness can be obtained as compared with a conventional light-emitting device 10.

Referring to a light-emitting device 10 of a comparative example, the following will describe the process of conceiving the light-emitting device 10 according to the embodiments of the present disclosure by the disclosers of the present disclosure, starting with the light-emitting device 10 of the first embodiment.

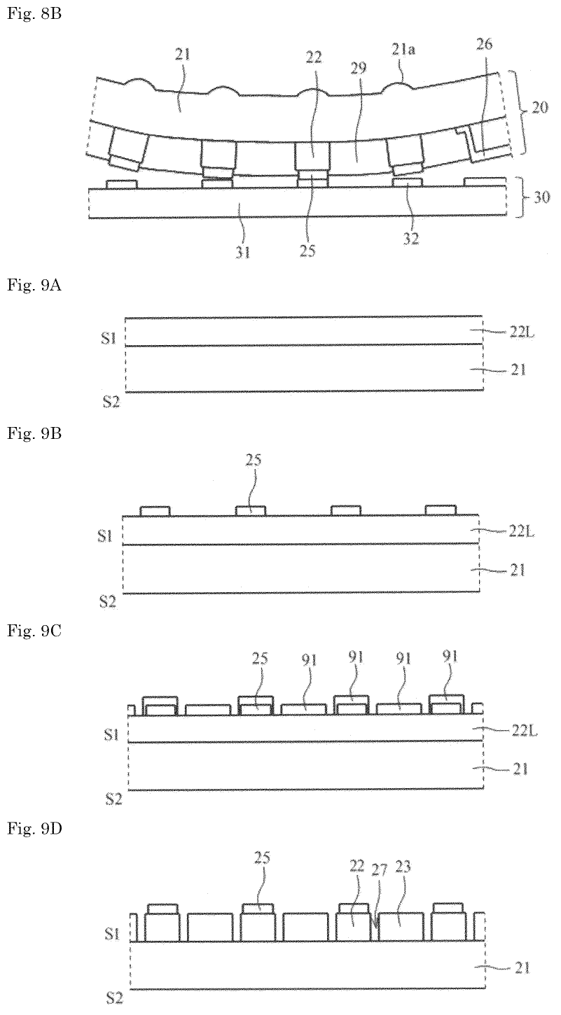

FIG. 7 is a longitudinal section illustrating the configuration of an LD chip 20 in the light-emitting device 10 according to the comparative example. FIGS. 8A and 8B are longitudinal sections schematically illustrating a method for manufacturing the light-emitting device 10 of the comparative example.

First, the disclosers of the present disclosure conceived that in order to improve flatness in the process of reducing the thickness of an LD substrate 21 and improve the reliability of the light-emitting device 10, an insulating resin, e.g., polyimide is to be embedded in interelement regions between a plurality of light-emitting elements 22 of the LD chip as illustrated in FIG. 7.

However, the disclosers of the present disclosure reached a study result revealing that the LD chip 20 configured thus cannot obtain an expected effect. Furthermore, the disclosers of the present disclosure found that the reason is the occurrence of slight warpage on the LD chip 20 due to a difference in the coefficient of thermal expansion between resin and the substrate 21 when the LD chip 20 is connected to the LDD board 30 in a high-temperature environment as illustrated in FIGS. 8A and 8B. In FIG. 8A, the size of warpage of the LD chip 20 is exaggerated.

Hence, the disclosers of the present disclosure advanced study about an insulating material filling an interelement region between the light-emitting elements 22 and suppression of the occurrence of warpage on the LD chip 20, so that the disclosers conceived the light-emitting device 10 according to the embodiment of the present disclosure.

The light-emitting device 10 conceived through the process according to the present disclosure allows the substrate 21 of the LD chip 20 to have a higher flatness with higher reliability as compared with the conventional light-emitting device 10.

In summary, the light-emitting device 10 of the first embodiment includes the LD chip 20 (first board), and the LD chip 20 (first board) includes the substrate 21 (first substrate), the light-emitting elements 22 that are disposed on the first side S1 of the substrate 21 (first substrate) and have the multilayer film 22L, and the structure 23 disposed in the interelement region between the light-emitting elements 22 on the first side S1. Furthermore, the structure 23 includes the same multilayer film 22L as the light-emitting element 22.

The light-emitting device 10 configured thus includes the LD chip 20 (first board) having a high flatness with high reliability.

An example of a method for manufacturing the light-emitting device 10 of the first embodiment will be described below. The common electrode 26 is omitted for convenience of explanation. The common electrode 26 can be formed by applying a known technique as appropriate.

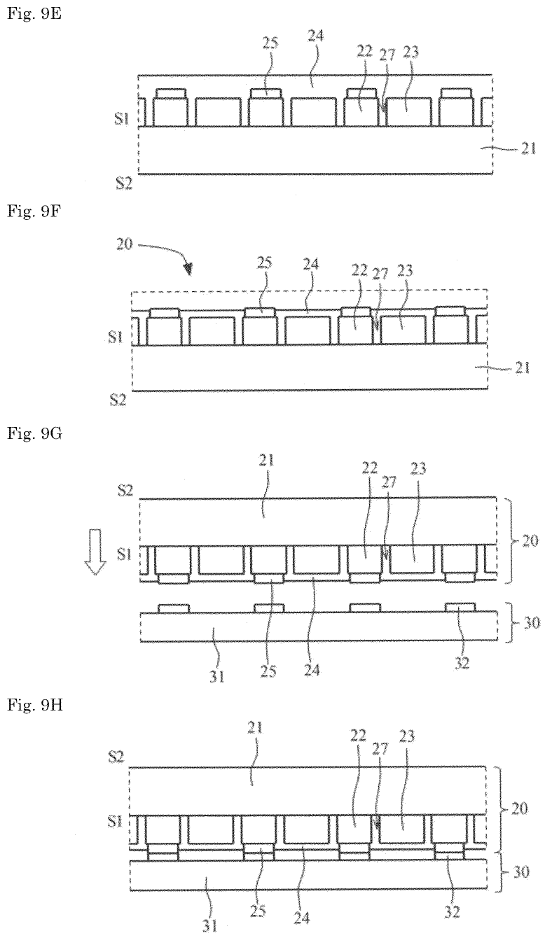

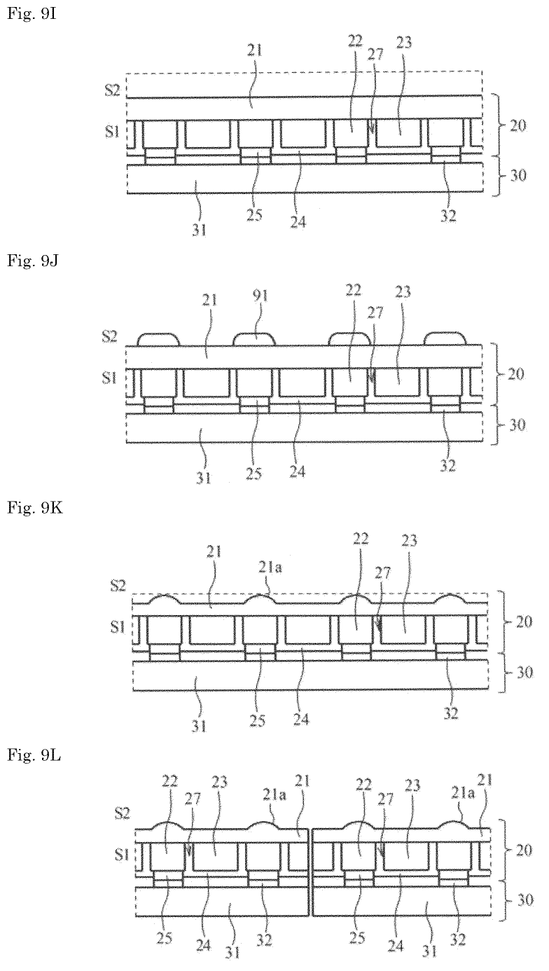

FIGS. 9A to 9L are longitudinal sections illustrating the example of the method for manufacturing the light-emitting device 10 of the first embodiment.

In the manufacturing of the light-emitting device 10 of the first embodiment, first, the multilayer film 22L constituting the light-emitting elements 22 is formed on the first side S1 of the substrate 21 as illustrated in FIG. 9A. The substrate 21 is a substrate made of a compound semiconductor, e.g., GaAs. The multilayer film 22A is formed by sequentially stacking the first mirror layer 221, the first spacer layer 222, the active layer 223, the second spacer layer 224, and the second mirror layer 225 (see FIG. 3) from the substrate 21. The multilayer film 22L can be formed by using, for example, a technique of epitaxial growth.

As illustrated in FIG. 9B, the individual electrodes 25 are subsequently formed in regions where the light-emitting elements 22 are to be formed on the multilayer film 22L. The individual electrode 25 is composed of a material suitable for direct bonding, e.g., thermocompression bonding. The individual electrode 25 is preferably composed of a metallic material and is more preferably composed of Cu or Au. For example, the individual electrodes 25 can be formed by sequentially performing resist coating, metallization, and resist removal.

As illustrated in FIGS. 9C and 9D, the light-emitting elements 22 and the structure 23 are then formed by removing the multilayer film 22L in regions where the gap portions 27 are to be formed between the light-emitting elements 22 and the structure 23. In the formation of the light-emitting elements 22 and the structure 23, as illustrated in FIG. 9C, a resist 91 is applied in regions other than regions where the gap portions 27 are to be formed on the multilayer film 22L and the individual electrodes 25. Thereafter, as illustrated in FIG. 9D, the multilayer film 22L is removed by etching in the regions where the gap portions 27 are to be formed, and then the resist 91 is also removed.

Subsequently, as illustrated in FIG. 9E, the insulator film 24 is stacked on the first side S1 of the substrate 21. The insulator film 24 is stacked so as to fill the gap portions 27 between the light-emitting elements 22 and the structure 23. The insulator film 24 is preferably composed of an inorganic material such as SiO₂ or SiN. The insulator film 24 can be stacked by, for example, ALD (Atomic Layer Deposition) or CVD (Chemical Vaper Deposition).

Subsequently, as illustrated in FIG. 9F, the individual electrodes 25 are exposed by polishing the insulator film 24 by CMP (Chemical Mechanical Polishing). Thus, the LD chip 20 connectable to the LDD board 30 can be obtained.

As illustrated in FIGS. 9G and 9H, the LD chip 20 obtained by the foregoing process is then bonded to the LDD board 30. At this point, the individual electrodes 25 of the LD chip 20 are directly bonded to the electrode pads 32 of the LDD board 30 by direct bonding, e.g., thermocompression bonding. Thereafter, a space between the LD chip 20 and the LDD board 30 may be filled with underfill.

Subsequently, as illustrated in FIG. 9I, the second side S2 of the substrate 21 of the LD chip 20 is polished by CMP (Chemical Mechanical Polishing), so that the thickness of the substrate 21 of the LD chip 20 is reduced.

Thereafter, as illustrated in FIGS. 9J and 9K, the lens portions 21a are formed on the second side S2 of the substrate 21 of the LD chip 20. In the formation of the lens portions 21a, as illustrated in FIG. 9J, the resist 91 is first applied in regions where the lens portions 21a are to be formed on the second side S2 of the substrate 21. Thereafter, as illustrated in FIG. 9K, the lens portions 21a are formed by reducing the thickness of the substrate 21 by etching in regions other than the regions where the lens portions 21a are to be formed, and then the resist 91 is also removed.

Finally, as illustrated in FIG. 9L, dicing is performed as necessary. The light-emitting device 10 including the LD chip 20 and the LDD board 30 is typically divided into pieces, each including the plurality of light-emitting elements 22. The light-emitting device 10 of the first embodiment is manufactured by the foregoing steps.

In summary, the method for manufacturing the light-emitting device 10 of the first embodiment includes a first step of producing the LD chip 20 (first board), a second step of bonding the individual electrodes 25 (first electrode pads) of the LD chip 20 (first board) to the electrode pads 32 (second electrode pads) of the LDD board 30 (second board) including the substrate 31 (second substrate) and the electrode pads 32 (second electrode pads) disposed on the substrate 31 (second substrate), and a third step of reducing the thickness of the substrate 21 (first substrate) of the LD chip 20 (first board) from the second side S2.

According to the method for manufacturing the light-emitting device 10, the light-emitting device 10 having a high flatness with high reliability can be manufactured.

Light-emitting devices 10 according to second to seventh embodiments will be described below. In these embodiments, differences from the first embodiment will be mainly described, and descriptions about points shared with the first embodiment will be omitted as appropriate.

### Second Embodiment

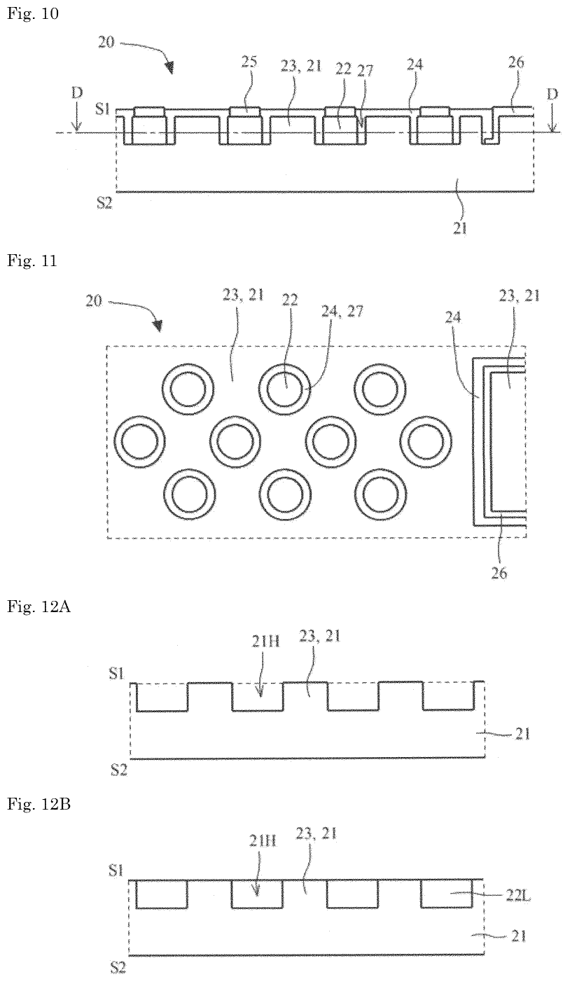

FIG. 10 is a longitudinal section illustrating the configuration of an LD chip 20 in a light-emitting device 10 according to a second embodiment. FIG. 11 is a cross section illustrating the configuration of the LD chip 20 in the light-emitting device 10 of the second embodiment. The cross section is taken along line D-D of FIG. 10.

Unlike the light-emitting device 10 of the first embodiment, the light-emitting device 10 of the second embodiment includes the LD chip 20 configured with structures 23 and 21 composed of the same material as a substrate 21. In the example of FIG. 10, the structures 23 and 21 and the substrate 21 are integrally configured. The structures 23 and 21 do not necessarily have to be integrally configured with the substrate 21. However, the structures 23 and 21 are preferably configured to be integrated with the substrate 21 in view of the strength and flatness of the LD chip 20.

Other configurations of the second embodiment are identical to those of the light-emitting device 10 of the first embodiment.

The light-emitting device 10 of the second embodiment includes the LD chip 20 configured with the structures 23 and 21 composed of the same material as the substrate 21, thereby further reinforcing the strength of the LD chip 20 and suppressing the occurrence of warpage on the LD chip 20 as compared with the light-emitting device 10 of the first embodiment.

An example of a method for manufacturing the light-emitting device 10 of the second embodiment will be described below.

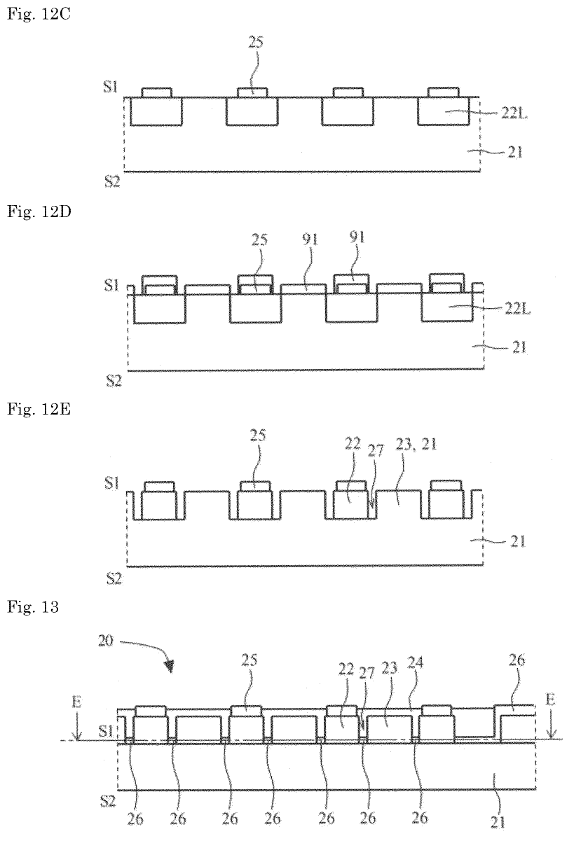

FIGS. 12A to 12E are longitudinal sections illustrating the example of the method for manufacturing the light-emitting device 10 of the second embodiment.

In the manufacturing of the light-emitting device 10 of the second embodiment, as illustrated in FIG. 12A, holes are first formed to a certain depth in a region other than a region to be formed as the structure 23 on a first side S1 of the substrate 21 of the LD chip 20, so that well portions 21H and the structures 23 and 21 are formed. The substrate 21 is a substrate made of a compound semiconductor such as GaAs. For example, the well portions 21H can be formed by the formation of a hard mask, dry etching, and the removal of the hard mask in sequence.

Subsequently, as illustrated in FIG. 12B, a multilayer film 22L constituting a light-emitting element 22 is formed in the well portion 21H. The multilayer film 22A is formed by sequentially stacking a first mirror layer 221, a first spacer layer 222, an active layer 223, a second spacer layer 224, and a second mirror layer 225 (see FIG. 3) from the substrate 21. The multilayer film 22L can be formed by using, for example, a technique of epitaxial growth.

Thereafter, as illustrated in FIG. 12C, individual electrodes 25 are formed in regions where the light-emitting elements 22 are to be formed on the multilayer film 22L. The individual electrode 25 is composed of a material suitable for direct bonding, e.g., thermocompression bonding. The individual electrode 25 is preferably composed of a metallic material and is more preferably composed of Cu or Au. For example, the individual electrodes 25 can be formed by sequentially performing resist coating, metallization, and resist removal.

Subsequently, as illustrated in FIGS. 12D and 12E, the light-emitting elements 22 and the structures 23 and 21 are then formed by removing the multilayer film 22L in regions where gap portions 27 are to be formed between the light-emitting elements 22 and the structures 23 and 21. In the formation of the light-emitting elements 22 and the structures 23 and 21, as illustrated in FIG. 12D, a resist 91 is applied in regions other than regions where the gap portions 27 are to be formed on the multilayer film 22L, the structures 23 and 21, and the individual electrodes 25. Thereafter, as illustrated in FIG. 12E, the multilayer film 22L is removed by etching in the regions where the gap portions 27 are to be formed, and then the resist 91 is also removed.

The subsequent steps are identical to those in the method for manufacturing the light-emitting device 10 according to the first embodiment illustrated in FIGS. 9E to 9L. The light-emitting device 10 of the second embodiment is manufactured by the foregoing steps.

### Third Embodiment

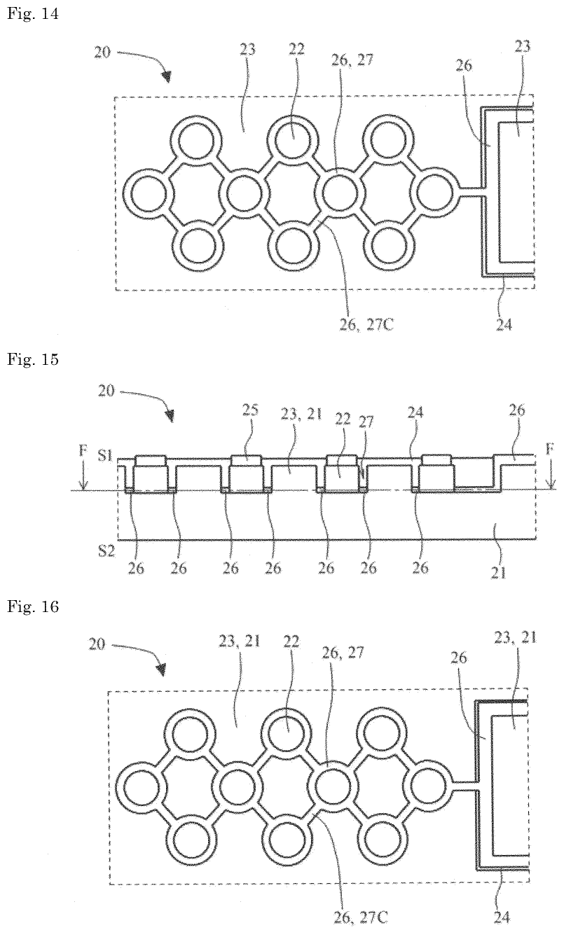

FIG. 13 is a longitudinal section illustrating the configuration of an LD chip 20 in a light-emitting device 10 according to a third embodiment. FIG. 14 is a cross section illustrating the configuration of the LD chip 20 in the light-emitting device 10 of the third embodiment. The cross section is taken along line E-E of FIG. 13.

In the light-emitting device 10 of the third embodiment, the common electrode 26 of the LD chip 20 in the light-emitting device 10 of the first embodiment is extended to a first side S1 of a substrate 21, the first side S1 serving as the bottom of a gap portion 27 between a light-emitting element 22 and a structure 23. In other words, an LD chip 30 in the light-emitting device 10 of the third embodiment includes a common electrode 26 extended onto the first side S1 of the substrate 21, the first side S1 serving as the bottom of the gap portion 27 between the light-emitting element 22 and the structure 23.

In the example of FIG. 14, in order to extend the common electrode 26 over the plurality of gap portions 27 corresponding to the plurality of light-emitting elements 22, a connecting portion 27C connecting the adjacent gap portions 27 is provided. The extended common electrode is disposed on the first side S1 of the substrate 21, the first side S1 serving as the bottom of the gap portion 27 and the connecting portion 27C.

Other configurations of the light-emitting device 10 of the third embodiment are identical to those of the light-emitting device 10 of the first embodiment.

In the light-emitting device 10 of the third embodiment, the common electrode 25 is connected to the substrate 21 near the outer peripheral portions of the light-emitting elements 22. Thus, the light-emitting elements 22 can be controlled with higher accuracy and stability as compared with the light-emitting device 10 of the first embodiment.

The light-emitting device 10 of the third embodiment can be manufactured by the same method as the light-emitting device 10 of the first embodiment. However, in the step of removing a multilayer film 22L in regions where the gap portions 27 illustrated in FIGS. 9C and 9D are to be formed in the manufacturing of the light-emitting device 10 of the third embodiment, the multilayer film 22L is removed also in a region where the connecting portion 27C is to be formed. Before the step of stacking an insulator film 24 in FIG. 9E, the step of stacking the common electrode 26 on the first side S1 of the substrate 21 is added, the first side S1 serving as the bottom of the gap portion 27 and the connecting portion 27C.

### Fourth Embodiment

FIG. 15 is a longitudinal section illustrating the configuration of an LD chip 20 in a light-emitting device 10 according to a fourth embodiment. FIG. 16 is a cross section illustrating the configuration of the LD chip 20 in the light-emitting device 10 according to the fourth embodiment. The cross section is taken along line F-F of FIG. 15.

In the light-emitting device 10 of the fourth embodiment, the common electrode 26 of the LD chip 20 in the light-emitting device 10 of the second embodiment is extended to a first side S1 of a substrate 21, the first side S1 serving as the bottom of a gap portion 27 between a light-emitting element 22 and structures 23 and 21. In other words, an LD chip 30 in the light-emitting device 10 of the fourth embodiment includes a common electrode 26 extended onto the first side S1 of the substrate 21, the first side S1 serving as the bottom of the gap portion 27 between the light-emitting element 22 and the structures 23 and 21.

In the example of FIG. 14, in order to extend the common electrode 26 over the plurality of gap portions 27 corresponding to the plurality of light-emitting elements 22, a connecting portion 27C connecting the adjacent gap portions 27 is provided. The extended common electrode is disposed on the first side S1 of the substrate 21, the first side S1 serving as the bottom of the gap portion 27 and the connecting portion 27C.

Other configurations of the light-emitting device 10 of the third embodiment are identical to those of the light-emitting device 10 of the first embodiment.

In the light-emitting device 10 of the fourth embodiment, the common electrode 25 is connected to the substrate 21 near the outer peripheral portions of the light-emitting elements 22. Thus, the light-emitting elements 22 can be controlled with higher accuracy and stability as compared with the light-emitting device 10 of the second embodiment.

The light-emitting device 10 of the fourth embodiment can be manufactured by the same method as the light-emitting device 10 of the second embodiment. However, in the step of forming well portions 21H and the structures 23 and 21 illustrated in FIG. 12A in the manufacturing of the light-emitting device 10 of the fourth embodiment, the well portions 21H are formed also in a region where the connecting portion 27C is to be formed. Moreover, in the step of removing a multilayer film 22L in regions where the gap portions 27 illustrated in FIGS. 12D and 12E are to be formed, the multilayer film 22L is removed also in a region where the connecting portion 27C is to be formed. Furthermore, before the subsequent step of stacking an insulator film 24 (see FIG. 9E), the step of stacking the common electrode 26 on the first side S1 of the substrate 21 is added, the first side S1 serving as the bottom of the gap portion 27 and the connecting portion 27C.

### Fifth Embodiment

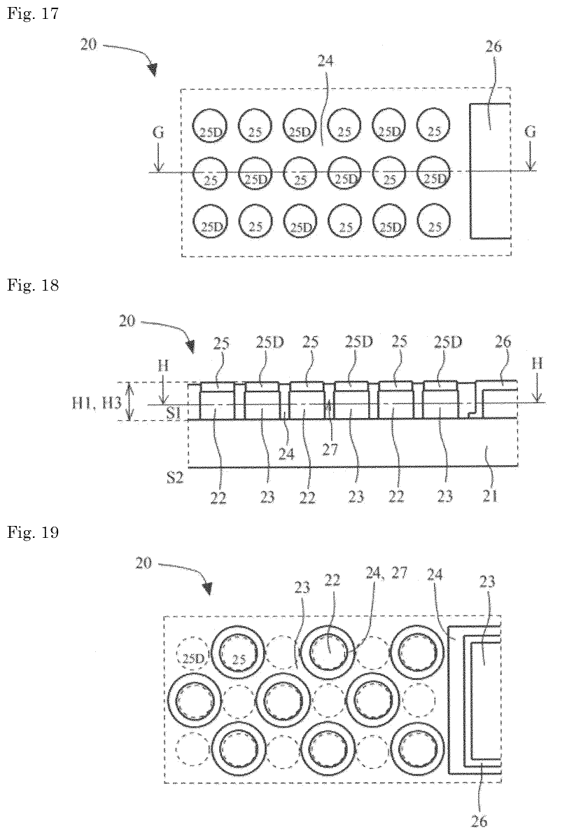

FIG. 17 is a front view illustrating the configuration of an LD chip 20 in a light-emitting device 10 of the fifth embodiment. FIG. 18 is a longitudinal section illustrating the configuration of the LD chip 20 in the light-emitting device 10 of the fifth embodiment. The longitudinal section is taken along line G-G of FIG. 17. FIG. 19 is a cross section illustrating the configuration of the LD chip 20 in the light-emitting device 10 of the fifth embodiment. The cross section is taken along line H-H of FIG. 18.

In addition to the configuration of the light-emitting device 10 of the first embodiment, the light-emitting device 10 of the fifth embodiment includes the LD chip 20 configured with dummy electrode pads 25D disposed at the tops of structures 23.

The dummy electrode pad 25D is composed of the same material as an individual electrode 25. The top of the dummy electrode pad 25D has a height H3 equal to a height H1 of the top of the individual electrode. Moreover, the dummy electrode pads 25D are exposed from an insulator film 24 to the outside like the individual electrodes 25. However, unlike the individual electrodes 25, the dummy electrode pads 25D are not bonded to electrode pads 32 of an LDD board 30 and do not receive driving signals supplied from the LDD board 30.

Other configurations of the light-emitting device 10 of the fifth embodiment are identical to those of the light-emitting device 10 of the first embodiment.

In the light-emitting device 10 of the fifth embodiment, in-plane uniformity improves on a first side S1 of a substrate 21 of the LD chip 20 in the presence of the dummy electrode pads 25D. Thus, bonding between the LD chip 20 and the LDD board 30 improves as compared with the light-emitting device 10 of the first embodiment.

The light-emitting device 10 of the fifth embodiment can be manufactured by the same method as the light-emitting device 10 of the first embodiment. However, in the step of forming the individual electrodes 25 illustrated in FIG. 9B in the manufacturing of the light-emitting device 10 of the fifth embodiment, the dummy electrode pads 25D are simultaneously formed in regions where the structures 23 are to be formed on the multilayer film 22L. Furthermore, in the step of exposing the individual electrodes 25 by polishing the insulator film 24 in FIG. 9F by CMP, the dummy electrode pads 25D are also exposed at the same time.

### Sixth Embodiment

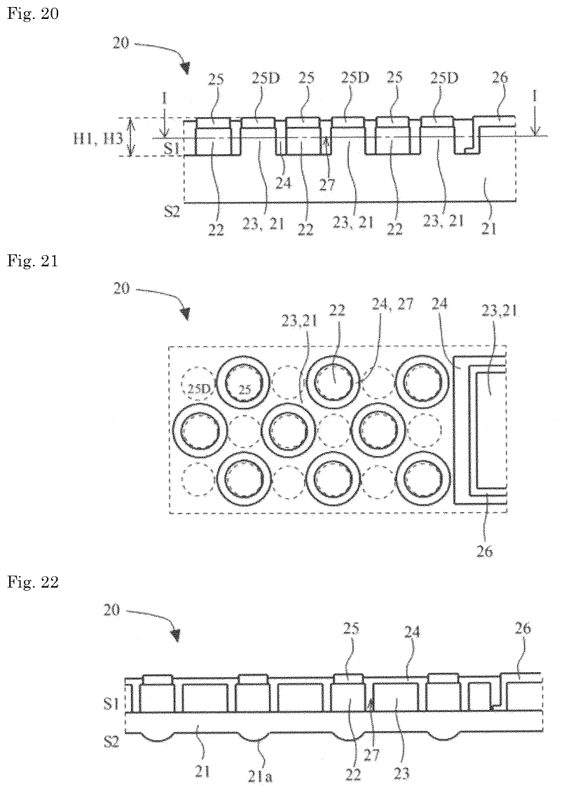

FIG. 20 is a longitudinal section illustrating the configuration of an LD chip 20 in a light-emitting device 10 according to a sixth embodiment. FIG. 21 is a cross section illustrating the configuration of the LD chip 20 in the light-emitting device 10 according to the sixth embodiment. The cross section is taken along line I-I of FIG. 20.

In addition to the configuration of the light-emitting device 10 of the second embodiment, the light-emitting device 10 of the sixth embodiment includes the LD chip 20 configured with dummy electrode pads 25D disposed at the tops of structures 23 and 21.

The dummy electrode pad 25D is composed of the same material as an individual electrode 25. The top of the dummy electrode pad 25D has a height H3 equal to a height H1 of the top of the individual electrode. Moreover, the dummy electrode pads 25D are exposed from an insulator film 24 to the outside like the individual electrodes 25. However, unlike the individual electrodes 25, the dummy electrode pads 25D are not bonded to electrode pads 32 of an LDD board 30 and do not receive driving signals supplied from the LDD board 30.

Other configurations of the light-emitting device 10 of the sixth embodiment are identical to those of the light-emitting device 10 of the second embodiment.

In the light-emitting device 10 of the fifth embodiment, in-plane uniformity improves on a first side S1 of the LD chip 20 in the presence of the dummy electrode pads 25D. Thus, bonding between the LD chip 20 and the LDD board 30 improves as compared with the light-emitting device 10 of the second embodiment.

The light-emitting device 10 of the sixth embodiment can be manufactured by the same method as the light-emitting device 10 of the second embodiment. However, in the step of forming the individual electrodes 25 illustrated in FIG. 12C in the manufacturing of the light-emitting device 10 of the sixth embodiment, the dummy electrode pads 25D are formed on the structures 23 and 21 at the same time. Furthermore, in the step of exposing the individual electrodes 25 by polishing the insulator film 24 by CMP (FIG. 9F), the dummy electrode pads 25D are also exposed at the same time.

### Seventh Embodiment

FIG. 22 is a longitudinal section illustrating the configuration of an LD chip 20 in a light-emitting device 10 according to a seventh embodiment.

The light-emitting device 10 of the seventh embodiment only includes the LD chip 20. In this respect, the light-emitting device 10 of the seventh embodiment is different from the light-emitting device 10 of the first embodiment including the LDD board 30 bonded to the LD chip 20. The configuration of the LD chip 20 of the light-emitting device 10 according to the seventh embodiment is identical to that of the LD chip 20 of the light-emitting device 10 according to the first embodiment illustrated in FIG. 1.

In the light-emitting device 10 of the seventh embodiment, a substrate 21 of the LD chip 20 has a high flatness with high reliability. Furthermore, the light-emitting device 10 is configured to suppress the occurrence of warpage during bonding to the LDD board 30. A high flatness is kept with high reliability after bonding to the LDD board.

An example of a method for manufacturing the light-emitting device 10 of the seventh embodiment will be described below.

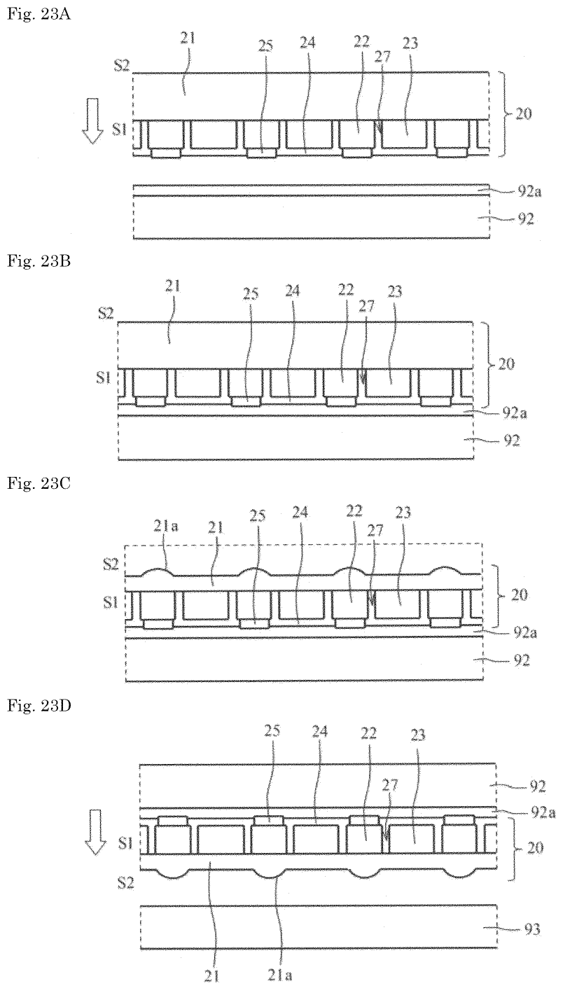

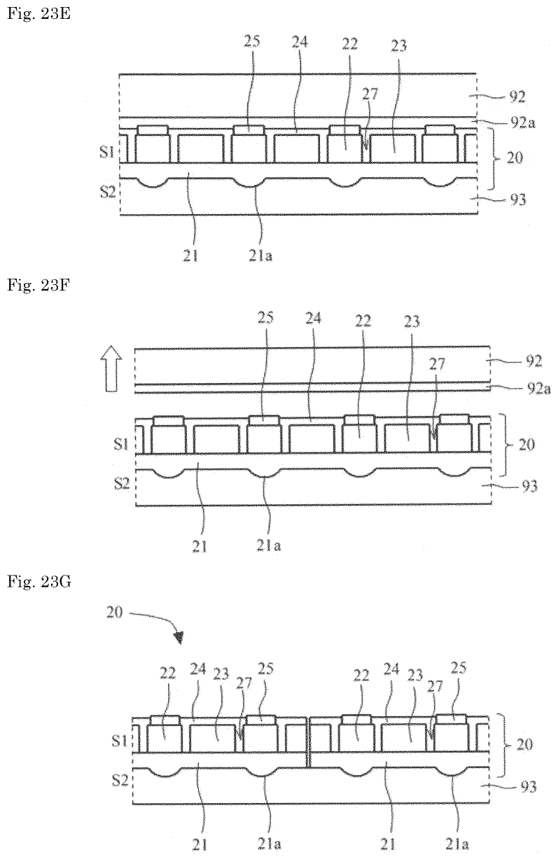

FIGS. 23A to 23G are longitudinal sections illustrating the example of the method for manufacturing the light-emitting device 10 of the seventh embodiment.

Until the LD chip 20 connectable to the LDD board 30 is obtained, the method for manufacturing the light-emitting device 10 of the seventh embodiment is identical to the method for manufacturing the light-emitting device 10 of the first embodiment illustrated in FIGS. 9A to 9F.

In the manufacturing of the light-emitting device 10 of the seventh embodiment, after the LD chip 20 connectable to the LDD board 30 is obtained, the LD chip 20 is bonded to a temporary substrate 92 as illustrated in FIGS. 23A and 23B. At this point, individual electrodes 25 of the LD chip 20 are bonded to the temporary substrate 92. The temporary substrate 92 includes an adhesive layer 92a for holding the LD chip 20. The adhesive layer 92a is composed of, for example, a material that decreases in adhesion through heating.

Thereafter, as illustrated in FIG. 23C, the thickness of the substrate 21 of the LD chip 20 is reduced, and then lens portions 21a are formed on the substrate 21. This step is identical to that in the method for manufacturing the light-emitting device 10 according to the first embodiment illustrated in FIGS. 9H to 9K.

Thereafter, as illustrated in FIGS. 23D and 23E, the LD chip 20 bonded to the temporary substrate 92 is bonded to a mount sheet 93. At this point, the lens portions 21a of the LD chip 20 are bonded to the mount sheet 93.

Subsequently, as illustrated in FIG. 23F, the temporary substrate 92 is removed from the LD chip 20. If the adhesive layer 92a of the temporary substrate 92 is composed of, for example, a material that decreases in adhesion through heating, the temporary substrate 92 can be removed from the LD chip 20 by heating the adhesive layer 92a.

Finally, as illustrated in FIG. 23G, dicing is performed as necessary. The LD chip 20 is typically divided into pieces, each including a plurality of light-emitting elements 22. The light-emitting device 10 of the seventh embodiment is manufactured by the foregoing steps.

An application example of the light-emitting device 10 according to the embodiments of the present disclosure will be described below.

### (Example of Application to Ranging Device)

The light-emitting device 10 according to the present embodiment can be used, for example, in a ranging device (also referred to as a ranging module) 40 that measures a distance to an object in a not-contact manner.

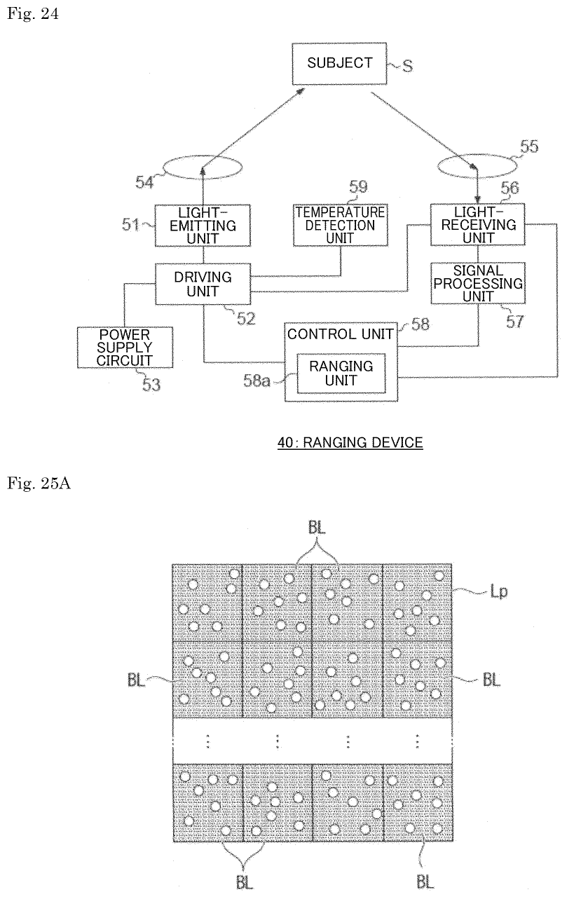

FIG. 24 is a block diagram illustrating a configuration example of the ranging device 40 as an implementation example of the light-emitting device 10 according to the embodiment of the present disclosure.

As illustrated in FIG. 24, the ranging device 40 includes a light-emitting unit 51, a driving unit 52, a power supply circuit 53, a light-emitting side optical system 54, a light-receiving side optical system 55, a light-receiving unit 56, a signal processing unit 57, a control unit 58, and a temperature detection unit 59.

The light-emitting unit 51 emits light using a plurality of light sources. As will be described later, the light-emitting unit 51 of the present example includes a plurality of light-emitting elements using VCSELs (Vertical Cavity Surface Emitting LASER) as light sources and is configured such that the light-emitting elements are arranged in a predetermined form, e.g., a matrix.

The driving unit 52 is configured with the power supply circuit 53 for driving the light-emitting unit 51. The power supply circuit 53 generates a power supply voltage (after-mentioned driving voltage Vd) of the driving unit 52 on the basis of, for example, an input voltage (after-mentioned input voltage Vin) from a battery or the like, which is not illustrated, in the ranging device 40. The driving unit 52 drives the light-emitting unit 51 on the basis of the power supply voltage.

Light emitted from the light-emitting unit 51 is projected to a subject (object) S, which is a target of ranging, through the light-emitting side optical system 54. Light reflected from the subject S enters the light receiving surface of the light-receiving unit 56 through the light-receiving side optical system 55.

The light-receiving unit 56 is a light-receiving element, e.g., a CCD (Charge Coupled Device) sensor or a CMOS (Complementary Metal Oxide Semiconductor) sensor. The light-receiving unit 56 receives light that is reflected from the subject S and enters the light receiving surface through the light-receiving side optical system 55 as described above, converts the light into an electric signal, and outputs the electric signal.

The light-receiving unit 56 executes, for example, CDS (Correlated Double Sampling) processing or AGC (Automatic Gain Control) processing for the electric signal obtained by photoelectric conversion of received light, and further performs A/D (Analog/Digital) conversion processing. Thereafter, a signal as digital data is output to the signal processing unit 57 in the subsequent stage.

Moreover, the light-receiving unit 56 according to the present example outputs a frame synchronizing signal Fs to the driving unit 52. Thus, the driving unit 52 can cause the light-emitting element 22 in the light-emitting unit 51 to emit light with timing corresponding to the frame period of the light-receiving unit 56.

The signal processing unit 57 is configured as a signal processor by, for example, a DSP (Digital Signal Processor). The signal processing unit 57 performs various kinds of signal processing on a digital signal input from the light-receiving unit 56.

The control unit 58 is configured with a microcomputer including, for example, a CPU (Central Processing Unit), a ROM (Read Only Memory), and RAM (Random Access Memory) or is configured with an information processor such as a DSP. The control unit 58 controls the driving unit 52 to control a light-emitting operation by the light-emitting unit 51 and controls a light receiving operation by the light-receiving unit 56.

The control unit 58 has a function as a ranging unit 58a. The ranging unit 58a measures a distance to the subject S on the basis of a signal (that is, a signal obtained by receiving light reflected from the subject S) input through the signal processing unit 57. The ranging unit 58a of the present example measures a distance to each part of the subject S in order to identify the three-dimensional shape of the subject S.

A specific ranging method in the ranging device 40 will be described later.

The temperature detection unit 59 detects a temperature of the light-emitting unit 51. The temperature detection unit 59 may be configured to detect a temperature by using, for example, a diode. In the present example, information about a temperature detected by the temperature detection unit 59 is supplied to the driving unit 52, so that the driving unit 52 can drive the light-emitting unit 51 on the basis of information about the temperature.

As a ranging method in the ranging device 40, a ranging method such as an STL (Structured Light) method or a ToF (Time of Flight) method can be adopted.

The STL method is a method for measuring a distance on the basis of an image of the subject S irradiated with light having a predetermined bright/dark pattern, e.g., a dot pattern or a grid pattern.

FIG. 25A is an explanatory drawing of the STL method. In the STL method, for example, pattern light Lp in a dot pattern illustrated in FIG. 25A is projected to the subject S. The pattern light Lp is divided into a plurality of blocks BL, and the blocks BL are allocated with different dot patterns (an overlap is avoided between the blocks B).

FIG. 25B is an explanatory drawing of the ranging principle of the STL method. In this example, a wall W and a box BX disposed in front of the wall W serve as the subject S and pattern light Lp is projected to the subject S. In the drawing, “G” schematically represents an angle of view formed by the light-receiving unit 56.

Moreover, “BLn” in the drawing indicates the light of one of the blocks BL in the pattern light Lp, and “dn” indicates the dot pattern of a block BLn in a received-light image generated by the light-receiving unit 56.

In the absence of the box BX in front of the wall W, the dot pattern of the block BLn in the received-light image is shown at the position of “dn” in the drawing. In other words, the position where the pattern of the block BLn in the received-light image is shown changes, to be specific, the pattern deforms depending upon the presence or absence of the box BX.

In the STL method, the shape and depth of the subject S are determined by using deformation of a projected pattern, the deformation depending upon the object shape of the subject S. Specifically, in this method, the shape and depth of the subject S are determined by pattern deformation.

When the STL method is adopted, for example, an IR (Infrared) light-receiving unit according to a global shutter method is used as the light-receiving unit 56. In the case of the STL method, the ranging unit 58a controls the driving unit 52 to cause the light-emitting unit 51 to emit pattern light, detects pattern deformation for an image signal obtained through the signal processing unit 57, and calculates a distance on the basis of the pattern deformation.

The ToF method is a method for measuring a distance to an object by detecting a time of flight of light that is emitted from the light-emitting unit 51 and is reflected by an object to reach the light-receiving unit 56.

When a so-called direct ToF (dTOF) method is adopted as a ToF method, the light-receiving unit 56 uses an SPAD (Single Photon Avalanche Diode) and the light-emitting unit 51 performs pulse driving. In this case, the ranging unit 58a calculates a time difference from emission to reception of light that is emitted from the light-emitting unit 51 and is received by the light-receiving unit 56, on the basis of a signal input through the signal processing unit 57, and the ranging unit 58a calculates a distance to each part of the subject S on the basis of the time difference and the speed of light.

When a so-called indirect ToF (iTOF) method (phase difference method) is adopted as a ToF method, for example, a light-receiving unit capable of receiving IR is used as the light-receiving unit 56.

An example of the ranging device was described, to which the light-emitting device 10 according to the embodiment of the present disclosure is applicable. The light-emitting device 10 according to the embodiment of the present disclosure is applicable to the light-emitting unit 51 and the light-emitting side optical system 54 among the foregoing configurations. Specifically, the ranging device 40 can be configured with the light-emitting device 10 according to the embodiment of the present disclosure, the light-receiving unit 56, and a distance measuring unit (ranging unit 58a) that measures a distance to an object on the basis of the light-emitting signal of the light-emitting device 10 and the light-receiving signal of the light-receiving unit 56 when the light-emitting signal of the light-emitting device 10 is reflected by the object and is received by the light-receiving unit 56. The reliability of the ranging device 40 can be improved by applying the light-emitting device 10 according to the embodiment of the present disclosure to the light-emitting unit 51 and the light-emitting side optical system 54.

### (Application Example to Mobile Object)

The technique according to the present disclosure can be applied to various products. For example, the technique according to the present disclosure may be implemented as a device mounted on any type of mobile object such as an automobile, an electric automobile, a hybrid electric automobile, a motorcycle, a bicycle, a personal mobility device, an airplane, a drone, a ship, a robot, or the like.

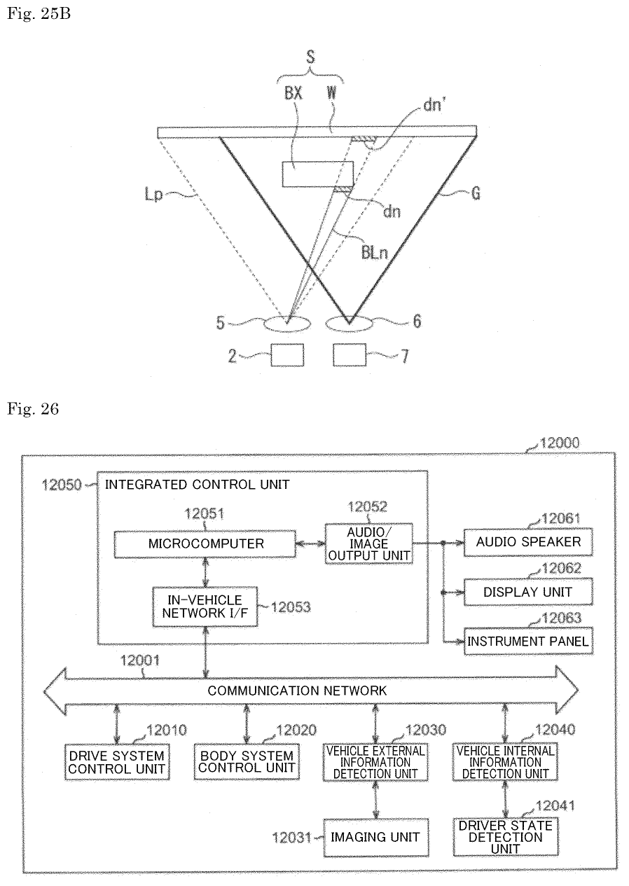

FIG. 26 is a block diagram illustrating a schematic configuration example of a vehicle control system 12000, which is an example of a mobile control system to which the technique according to the present disclosure can be applied.

A vehicle control system 12000 includes a plurality of electronic control units connected to each other via a communication network 12001. In the example illustrated in FIG. 26, the vehicle control system 12000 includes a drive system control unit 12010, a body system control unit 12020, a vehicle external information detection unit 12030, a vehicle internal information detection unit 12040, and an integrated control unit 12050. As a functional configuration of the integrated control unit 12050, a microcomputer 12051, an audio/image output unit 12052, and an in-vehicle network I/F (interface) 12053 are illustrated.

The drive system control unit 12010 controls the operation of the device related to the drive system of the vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted thereon. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for persons, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information input from the driver state detection unit 12041.

The microcomputer 12051 can calculate a control target value for the driving force generation device, the steering mechanism, or the braking device on the basis of information on the inside and outside of the vehicle, the information being acquired by the vehicle external information detection unit 12030 or the vehicle internal information detection unit 12040, and the microcomputer 12051 can output a control command to the drive system control unit 12010. For example, the microcomputer 12051 can perform cooperative control for the purpose of implementing the functions of an ADAS (Advanced Driver Assistance System) including vehicle collision avoidance, impact mitigation, following traveling based on an inter-vehicle distance, vehicle speed maintenance driving, vehicle collision warning, and vehicle lane deviation warning.

Furthermore, the microcomputer 12051 can perform cooperative control for the purpose of automated driving or the like in which autonomous driving is performed without operations of the driver, by controlling the driving force generator, the steering mechanism, or the braking device and the like on the basis of information about the surroundings of the vehicle, the information being acquired by the vehicle external information detection unit 12030 or the vehicle internal information detection unit 12040.

In addition, the microcomputer 12051 can output a control command to the body system control unit 12020 on the basis of the information acquired outside the vehicle by the vehicle external information detection unit 12030. For example, the microcomputer 12051 can perform cooperative control for the purpose of antiglare, for example, switching a high beam to a low beam by controlling a headlamp according to a position of a vehicle ahead or an oncoming vehicle detected by the vehicle external information detection unit 12030.

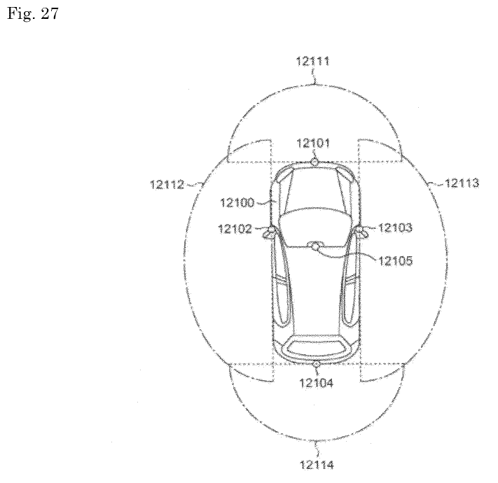

The audio/image output unit 12052 transmits an output signal of at least one of sound and an image to an output device capable of visually or audibly notifying information to a passenger or the outside of the vehicle. In the example of FIG. 26, an audio speaker 12061, a display unit 12062, and an instrument panel 12063 are illustrated as examples of the output device. The display unit 12062 may include, for example, at least one of an on-board display and a head-up display. FIG. 27 illustrates an example of the installation positions of the imaging unit 12031.

In FIG. 27, the imaging unit 12031 includes imaging units 12101, 12102, 12103, 12104, and 12105.

The imaging units 12101, 12102, 12103, 12104, and 12105 are provided at, for example, the positions of the front nose, side mirrors, rear bumper, back door of the vehicle 12100 and an upper portion of a windshield in the vehicle. The imaging unit 12101 provided at the front nose and the imaging unit 12105 provided in the upper portion of the windshield in the vehicle mainly acquire images ahead of the vehicle 12100. The imaging units 12102 and 12103 provided at the side mirrors mainly acquire images on the sides of the vehicle 12100. The imaging unit 12104 provided at the rear bumper or the back door mainly acquires an image of an area behind the vehicle 12100. The imaging unit 12105 provided in the upper portion of the windshield inside the vehicle is mainly used for detection of a vehicle ahead, a pedestrian, an obstacle, a traffic signal, a traffic sign, or a lane or the like.

FIG. 27 illustrates an example of the imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, a bird's-eye view image of the vehicle 12100 viewed from above can be obtained.

At least one of the imaging units 12101 to 12104 may have the function of acquiring distance information. For example, at least one of the imaging units 12101 to 12104 may be a stereo camera including a plurality of imaging elements or may be an imaging element that has pixels for phase difference detection.

For example, the microcomputer 12051 can extract, in particular, a closest three-dimensional object on a traveling path of the vehicle 12100, which is a three-dimensional object traveling at a predetermined speed (for example, 0 km/h or higher) in the substantially same direction as the vehicle 12100, as a vehicle ahead by obtaining a distance to each three-dimensional object in the imaging ranges 12111 to 12114 and temporal change in the distance (a relative speed with respect to the vehicle 12100) on the basis of distance information obtained from the imaging units 12101 to 12104. The microcomputer 12051 can also set a distance to be secured from a vehicle ahead and perform automatic brake control (including following stop control) and automatic acceleration control (including following start control). Thus, cooperative control can be performed for the purpose of, for example, automated driving in which autonomous driving is performed without operations of the driver.

For example, the microcomputer 12051 can classify and extract three-dimensional data regarding three-dimensional objects into two-wheeled vehicles, ordinary vehicles, large vehicles, pedestrians, and other three-dimensional objects such as electric poles on the basis of distance information obtained from the imaging units 12101 to 12104 and can use the three-dimensional data for automated avoidance of obstacles. For example, the microcomputer 12051 classifies obstacles around the vehicle 12100 into obstacles visible to the driver of the vehicle 12100 and obstacles hardly visible to the driver. Thereafter, the microcomputer 12051 determines a collision risk indicating the degree of risk of collision with each obstacle. When the collision risk is equal to or higher than a set value and there is a possibility of collision, an alarm is output to the driver through the audio speaker 12061 or the display unit 12062 and forced deceleration or avoidance steering is performed through the drive system control unit 12010, achieving driving support for collision avoidance.

At least one of the imaging units 12101 to 12104 may be an infrared camera that detects infrared rays. For example, the microcomputer 12051 can recognize a pedestrian by determining the presence or absence of a pedestrian in captured images of the imaging units 12101 to 12104. Such pedestrian recognition is performed by, for example, the step of extracting feature points in the captured images of the imaging units 12101 to 12104 as infrared cameras and the step of pattern matching on a series of feature points indicating an outline of an object to determine whether or not the object is a pedestrian. When the microcomputer 12051 determines that a pedestrian is present in the captured images of the imaging units 12101 to 12104 and recognizes the pedestrian, the audio/image output unit 12052 controls the display unit 12062 such that a square contour line for emphasis is superimposed and displayed on the recognized pedestrian. In addition, the audio/image output unit 12052 may control the display unit 12062 such that an icon or the like indicating a pedestrian is displayed at a desired position.

An example of the vehicle control system to which the technique according to the present disclosure is applicable was described above. The technique according to the present disclosure can be applied to the imaging unit 12031 among the configurations described above. Specifically, the light-emitting device 10 according to the present disclosure is preferably provided along with the imaging unit 12031. By applying the technique according to the present disclosure to the imaging unit 12031, the resolution of a depth map can be increased while suppressing the occurrence of electromagnetic noise, thereby improving the functionality and safety of the vehicle 12100.

### 6. SUMMARY

Although the example of the embodiment of the present disclosure was described above, the present disclosure can be implemented in other various forms. For example, various modifications, substitutions, omissions, or combinations thereof are possible without departing from the gist of the present disclosure. Such forms of modifications, substitutions, and omissions are included in the scope of the invention described in the claims and the scope of equivalence thereof, as included in the scope of the present disclosure.

In addition, the effects of the present disclosure described herein are merely exemplary and may have other effects.

The present disclosure can also be configured as follows:

### [Item 1]

A light-emitting device including a first board,
the first board including:
a first substrate;
light-emitting elements, each being disposed on a first side of the first substrate and having a multilayer film; and
a structure that is disposed in an interelement region between the light-emitting elements on the first side,
wherein the structure has the same multilayer film as the light-emitting element or is composed of the same material as the first substrate.

### [Item 2]

The light-emitting device according to item 1,
wherein the first board further includes an insulator film stacked on the first side to fill a gap portion between the light-emitting element and the structure.

### [Item 3]

The light-emitting device according to item 2,
wherein the insulator film is composed of an inorganic material.

### [Item 4]

The light-emitting device according to any one of items 1 to 3,
wherein the first board includes a first electrode pad disposed at the top of the light-emitting element, and
the top of the structure has a height lower than the height of the top of the first electrode pad.

### [Item 5]

The light-emitting device according to any one of items 1 to 4,
wherein the first board further includes a common electrode extended to the first side of the first substrate, the first side serving as the bottom of the gap portion between the light-emitting element and the structure.

### [Item 6]

The light-emitting device according to any one of claims 1 to 5,
wherein the first board further includes a first electrode pad disposed at the top of the light-emitting element, and a dummy electrode pad disposed at the top of the structure.

### [Item 7]

The light-emitting device according to any one of items 1 to 6,
wherein the first board further includes a lens portion that is provided on a second side opposite to the first side of the first substrate and condenses light emitted from the light-emitting element.

### [Item 8]

The light-emitting device according to any one of items 1 to 7,
further including a second board bonded to the first board,
wherein the second board includes a second substrate and a second electrode pad disposed on the second substrate, and
the first electrode pad of the first board and the second electrode pad of the second board are bonded to each other.

### [Item 9]

The light-emitting device according to item 8,
wherein the first electrode pad and the second electrode pad are bonded by direct bonding.

### [Item 10]

A method for manufacturing a light-emitting device, the method including: a first step of producing a first board including a first substrate, light-emitting elements, each being disposed on a first side of the first substrate and having a multilayer film, a structure that is disposed in an interelement region between the light-emitting elements on the first side, and a first electrode pad disposed at the top of the light-emitting element, the structure having the same multilayer film as the light-emitting element or being composed of the same material as the first substrate;
a second step of bonding the first electrode pad of the first board to a second electrode pad of a second board, the second board including a second substrate and the second electrode pad disposed on the second substrate; and
a third step of reducing the thickness of the first substrate from a second side opposite to the first side.

### [Item 11]

The method for manufacturing a light-emitting device according to item 10, further including a fourth step of forming a lens portion that condenses light emitted from the light-emitting element on the second side of the first substrate.

### [Item 12]

A ranging device including a light-emitting device, a light-receiving unit, and a distance measuring unit that measures a distance to an object on the basis of the light-emitting signal of the light-emitting device and the light-receiving signal of the light receiving unit when the light-emitting signal of the light-emitting device is reflected by the object and is received by the light-receiving unit, the light-emitting device including:
a first substrate;
light-emitting elements, each being disposed on a first side of the first substrate and having a multilayer film; and
a structure that is disposed in an interelement region between the light-emitting elements on the first side,
wherein the structure has the same multilayer film as the light-emitting element or is composed of the same material as the first substrate.

### REFERENCE SIGNS LIST

10 Light-emitting device
20 LD chip (first board)
21 Substrate (first substrate)
21a Lens portion
21H Well portion
22 Light-emitting element
22L Multilayer film
221 First mirror layer
222 First spacer layer
223 Active layer
224 Second spacer layer
225 Second mirror layer
23 Structure
24 Insulator film
25 Individual electrode (first electrode pad)
25D Dummy electrode pad
26 Common electrode
27 Gap portion
27C Connecting portion
30 LDD board (second board)
31 Substrate (second substrate)
32 Electrode pad (second electrode pad)
91 Register
92 Temporary substrate
92a Adhesive layer
93 Mount sheet

1. A light-emitting device comprising a first board,
the first board including:
a first substrate;
light-emitting elements, each being disposed on a first side of the first substrate and having a multilayer film; and
a structure that is disposed in an interelement region between the light-emitting elements on the first side,
wherein the structure has the same multilayer film as the light-emitting element or is composed of the same material as the first substrate.

2. The light-emitting device according to claim 1,
wherein the first board further includes an insulator film stacked on the first side to fill a gap portion between the light-emitting element and the structure.

3. The light-emitting device according to claim 2,
wherein the insulator film is composed of an inorganic material.

4. The light-emitting device according to claim 1,
wherein the first board includes a first electrode pad disposed at a top of the light-emitting element, and
a top of the structure has a height lower than a height of a top of the first electrode pad.

5. The light-emitting device according to claim 1,
wherein the first board further includes a common electrode extended to the first side of the first substrate, the first side serving as a bottom of a gap portion between the light-emitting element and the structure.

6. The light-emitting device according to claim 1,
wherein the first board further includes a first electrode pad disposed at a top of the light-emitting element, and a dummy electrode pad disposed at a top of the structure.

7. The light-emitting device according to claim 1,
wherein the first board further includes a lens portion that is provided on a second side opposite to the first side of the first substrate and condenses light emitted from the light-emitting element.

8. The light-emitting device according to claim 1,
further including a second board bonded to the first board,
wherein the second board includes a second substrate and a second electrode pad disposed on the second substrate, and
the first electrode pad of the first board and the second electrode pad of the second board are bonded to each other.

9. The imaging device according to claim 8,
wherein the first electrode pad and the second electrode pad are bonded by direct bonding.

10. A method for manufacturing a light-emitting device, the method comprising:
a first step of producing a first board including a first substrate, light-emitting elements, each being disposed on a first side of the first substrate and having a multilayer film, a structure that is disposed in an interelement region between the light-emitting elements on the first side, and a first electrode pad disposed at a top of the light-emitting element, the structure having the same multilayer film as the light-emitting element or being composed of the same material as the first substrate;
a second step of bonding the first electrode pad of the first board to a second electrode pad of a second board, the second board including a second substrate and the second electrode pad disposed on the second substrate; and
a third step of reducing a thickness of the first substrate from a second side opposite to the first side.

11. The method for manufacturing a light-emitting device according to claim 10, further including a fourth step of forming a lens portion that condenses light emitted from the light-emitting element on the second side of the first substrate.

12. A ranging device comprising a light-emitting device, a light-receiving unit, and a distance measuring unit that measures a distance to an object on a basis of a light-emitting signal of the light-emitting device and a light-receiving signal of the light-receiving unit when the light-emitting signal of the light-emitting device is reflected by the object and is received by the light-receiving unit,
the light-emitting device comprising:
a first substrate;
light-emitting elements, each being disposed on a first side of the first substrate and having a multilayer film; and
a structure that is disposed in an interelement region between the light-emitting elements on the first side,
wherein the structure has the same multilayer film as the light-emitting element or is composed of the same material as the first substrate.
